(19) United States
(12) Patent Application Publication
(10) Pub. No.: US 2025/0089235 A1
(43) Pub. Date: Mar. 13, 2025

(54) SEMICONDUCTOR DEVICES AND FABRICATING METHODS THEREOF

(71) Applicant: YANGTZE MEMORY TECHNOLOGIES CO., LTD., Wuhan (CN)

(72) Inventors: Dongxue Zhao, Wuhan (CN); Yuancheng Yang, Wuhan (CN); Tao Yang, Wuhan (CN); Changzhi Sun, Wuhan (CN); Wei Liu, Wuhan (CN); Zhiliang Xia, Wuhan (CN); Zongliang Huo, Wuhan (CN)

(21) Appl. No.: 18/374,524

(22) Filed: Sep. 28, 2023

Related U.S. Application Data
(63) Continuation of application No. PCT/CN2023/118232, filed on Sep. 12, 2023.

(51) Int. Cl. H10B 12/00; H01L 29/06; H01L 29/786

(52) U.S. Cl. CPC H10B 12/315; H10B 12/482; H10B 12/488; H10D 30/6728; H10D 62/102

(57) ABSTRACT

Three-dimensional (3D) semiconductor devices and fabricating methods are provided. In some implementations, a disclosed semiconductor device comprises a plurality of vertical transistors, each comprising: a semiconductor layer having a leakage value lower than a pico-ampere and comprising a vertical semiconductor portion and at least one lateral semiconductor portion, a gate dielectric layer comprising a vertical gate dielectric portion on the vertical semiconductor portion and extending in the vertical direction, a gate electrode on the gate dielectric layer and separated from the semiconductor layer by the gate dielectric layer. The disclosed semiconductor device further comprises a plurality of capacitors each coupled with the semiconductor layer of a corresponding one of the plurality of vertical transistors.

### CROSS-REFERENCE TO RELATED APPLICATIONS

This application is a continuation of International Application No. PCT/CN2023/118232, filed on Sep. 12, 2023, entitled “SEMICONDUCTOR DEVICES AND FABRICATiNG METHODS THEREOF,” which is incorporated herein by reference in its entirety.

### TECHNICAL FIELD

The present disclosure generally relates to the field of semiconductor technology, and more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

One aspect of the present disclosure provides a semiconductor device, comprising: a plurality of vertical transistors each comprising: a semiconductor layer having a leakage value lower than a pico-ampere and comprising a vertical semiconductor portion and at least one lateral semiconductor portion, a gate dielectric layer comprising a vertical gate dielectric portion on the vertical semiconductor portion and extending in the vertical direction, a gate electrode on the gate dielectric layer and separated from the semiconductor layer by the gate dielectric layer; and a plurality of capacitors each coupled with the semiconductor layer of a corresponding one of the plurality of vertical transistors.

In some implementations, the gate electrode extends along the vertical direction, and is laterally surrounded by the vertical gate dielectric portion.

In some implementations, the vertical gate dielectric portion is laterally surrounded by the vertical semiconductor portion.

In some implementations, the gate dielectric layer further comprises a lateral gate dielectric portion in contact with a first end of the gate electrode.

In some implementations, a first lateral semiconductor portion is between the lateral gate dielectric portion and one corresponding capacitor.

In some implementations, the semiconductor device further comprises word lines each extending along a first lateral direction and connected to second ends of the gate electrodes.

In some implementations, the semiconductor device further comprises bit lines each extending along a second lateral direction and in direct contact with the vertical semiconductor portions.

In some implementations, the bit line fully surrounds a sidewall of the vertical semiconductor portion and in contact with a second lateral semiconductor portion.

In some implementations, the bit line partially surrounds a sidewall of the vertical metal oxide semiconductor portion and in contact with a second lateral semiconductor portion.

In some implementations, the semiconductor device further comprises a conductive plug laterally surrounded by the vertical semiconductor portion, and connected to a bit line extending along a second lateral direction.

In some implementations, the vertical semiconductor portion is laterally surrounded by the vertical gate dielectric portion.

In some implementations, a word line comprises the gate electrodes connected with each other in a first lateral direction.

In some implementations, the word line at least partially surrounds the vertical gate dielectric portions of the row of the vertical transistors.

In some implementations, the leakage value of the semiconductor layer is lower than an intrinsic leakage value of monocrystalline silicon.

In some implementations, the semiconductor layer is a metal oxide semiconductor layer.

Another aspect of the present disclosure provides a semiconductor device, comprising: a plurality of vertical transistors each comprising: a gate electrode extending in a vertical direction, a gate dielectric layer laterally surrounding the gate electrode and covering a first end of the gate electrode, a semiconductor layer laterally surrounding the gate dielectric layer and covering a first end of the gate dielectric layer; a plurality of capacitors each coupled with the semiconductor layer of a corresponding one of the vertical transistors; a plurality of word lines each extending along a first lateral direction and coupled with the gate electrodes; and a plurality of bit lines each extending along a second lateral direction and coupled with the semiconductor layers.

In some implementations, the bit line at least partially surrounds the semiconductor layer of each vertical transistor in a lateral plane.

In some implementations, the leakage value of the semiconductor layer is lower than an intrinsic leakage value of monocrystalline silicon.

In some implementations, the semiconductor layer is a metal oxide semiconductor layer.

Another aspect of the present disclosure provides a method of forming a semiconductor device, comprising: forming a plurality of capacitors; forming a dielectric layer on the plurality of capacitors; forming a conductive layer on the dielectric layer; forming a plurality of through holes each penetrating the conductive layer and the dielectric layer to expose a corresponding one of the plurality of capacitors; forming a semiconductor layer to cover a bottom and a sidewall of each through hole; forming a gate dielectric layer to cover the semiconductor layer; and forming a gate electrode on the gate dielectric layer in each through hole.

In some implementations, the method further comprises, before forming the plurality of through holes, cutting the conductive layer to form a plurality of bit lines each extending along a second lateral direction.

In some implementations, the method further comprises forming a plurality of word lines each extending along a first lateral direction and coupled with the gate electrodes.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a memory device including an array of memory cells each having a vertical transistor, according to some implementations of the present disclosure.

FIG. 2A illustrates a schematic plan view of an array of memory cells each including a vertical transistor in a memory device, according to some implementations of the present disclosure.

FIG. 2B illustrates a schematic plan view of an array of memory cells each including a vertical transistor in a memory device, according to some implementations of the present disclosure.

FIG. 2C illustrates a schematic side view of a cross-section of a memory cell in a 3D memory device, according to some implementations of the present disclosure.

FIG. 2D illustrates a schematic side view of a cross-section of a memory cell in a 3D memory device, according to some implementations of the present disclosure.

FIG. 3A illustrates a schematic plan view of an array of memory cells each including a vertical transistor in a memory device, according to some implementations of the present disclosure.

FIG. 3B illustrates a schematic plan view of an array of memory cells each including a vertical transistor in a memory device, according to some implementations of the present disclosure.

FIG. 3C illustrates a schematic side view of a cross-section of a memory cell in a 3D memory device, according to some implementations of the present disclosure.

FIG. 3D illustrates a schematic side view of a cross-section of a memory cell in a 3D memory device, according to some implementations of the present disclosure.

FIG. 4 illustrates a block diagram of a system having a memory device, according to some implementations of the present disclosure.

FIG. 5 illustrates a flowchart of a fabricating method for forming a 3D memory device, according to some implementations of the present disclosure.

FIGS. 6A-6E each illustrates a schematic side cross-sectional view of a 3D memory device at a certain fabricating stage of the method shown in FIG. 5, according to various implementations of the present disclosure.

FIG. 7 illustrates a flowchart of a fabricating method for forming a 3D memory device, according to some implementations of the present disclosure.

FIGS. 8A-8E each illustrates a schematic side cross-sectional view of a 3D memory device at a certain fabricating stage of the method shown in FIG. 5, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some memory devices, such as dynamic radon access memory (DRAM). In a one-transistor-one-capacitor (1T1C) DRAM structure, the data are stored in the capacitors. There is a high requirement on the leakage issue of the selection transistors. Thus, it is necessary to identify alternative channel materials with a lower leakage compared to using the monocrystalline silicon as the channel material. Moreover, with the continuous scaling development of DRAM, the unit size of a 1T1C cell continues to decrease, thereby increasing the influence of the leakage issue of the selection transistors. Further, the etching aspect ratio of the capacitors increases, causing serious challenges in the fabricating processes and increased product cost.

To address one or more of the aforementioned issues, the present disclosure introduces a solution in which vertical transistors a memory cell array of memory devices (e.g., DRAM). In the disclosed memory devices, low-leakage materials, such as a metal oxide semiconductor material, are selected to use as the channel of the select transistors to solve the leakage problem in the process of DRAM scaling. The disclosed memory devices include two device structures, i.e., channel-all-around (CAA) type vertical channel transistors and gate-all-around (GAA) type vertical channel transistors. The corresponding fabricating processes of the two device structures are described, in which the vertical channel transistors can be formed on either front side or back side of the capacitors. By using the new channel material of the selection transistors in DRAM, the disclosed memory devices can have a high memory density with a further reduced cell size. The disclosed fabricating process can have a simplified source node (SN) contact process, thereby reducing the product cost.

Consistent with the scope of the present disclosure, according to some implementations of the present disclosure, the memory cell array having vertical transistors each comprising a semiconductor layer extending in a vertical direction, and a gate structure beside the semiconductor layer or surrounded by the semiconductor layer. In some implementations, the word lines and bit lines connected to the vertical transistors are arranged along a first lateral direction and a second lateral direction, respectively. Each of the semiconductor bodies of the array of vertical transistors extends along a vertical direction. By using such an arrangement, memory area efficiency can be increased. Further, the memory cell array and the peripheral circuits can be formed separately on different wafers, such that the fabricating processes of the memory cell array and the peripheral circuits do not affect each other, and the memory area efficiency can be further increased.

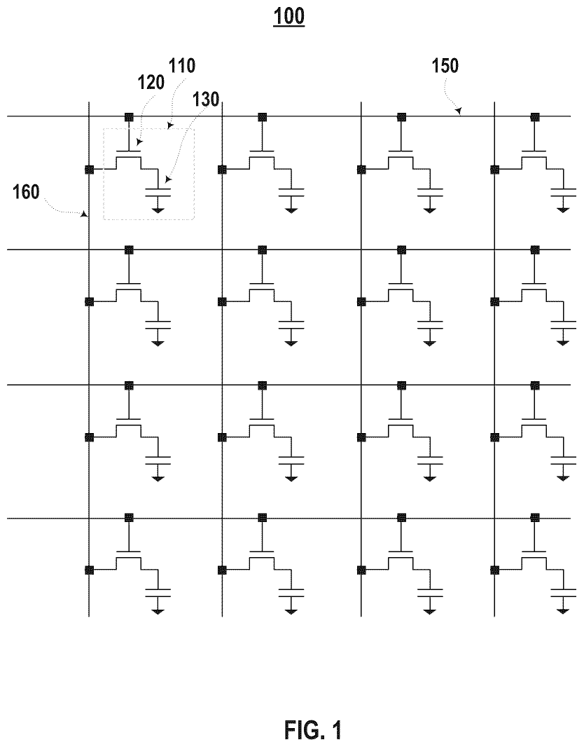

FIG. 1 illustrates a schematic diagram of a memory device 100 having an array of memory cells each having a vertical transistor, according to some implementations of the present disclosure. Memory device 100 can include a memory cell array in which each memory cell 110 includes a vertical transistor 120 and a storage unit coupled to vertical transistor 120. In some implementations as shown in FIG. 1, the memory cell array is a DRAM cell array, and the storage unit is a capacitor 130 for storing charge as the binary information stored by the respective DRAM cell. In some other implementations not shown in the figures, the memory cell array is a PCM cell array, and the storage unit can be a PCM element (e.g., including chalcogenide alloys) for storing binary information of the respective PCM cell based on the different resistivities of the PCM element in the amorphous phase and the crystalline phase.

As shown in FIG. 1, memory cells 110 can be arranged in a two-dimensional (2D) array having rows and columns. Memory device 100 can include word lines 150 coupling the memory cell array to peripheral circuits for controlling the switch of vertical transistors 120 in memory cells 110 located in a row, as well as bit lines 160 coupling the memory cell array to peripheral circuits for sending data to and/or receiving data from memory cells 110 located in a column. That is, each word line 150 is coupled to a respective row of memory cells 110, and each bit line 160 is coupled to one or more respective logic columns of memory cells 110. In some implementations, the gate of vertical transistor 120 is coupled to word line 150, one of the source and the drain of vertical transistor 120 is coupled to bit line 160, the other one of the source and the drain of vertical transistor 120 is coupled to one electrode of capacitor 130, and the other electrode of capacitor 130 is coupled to the ground.

Consistent with the scope of the present disclosure, vertical transistors 120, such as vertical metal-oxide-semiconductor field-effect transistors (MOSFETs), can replace the conventional planar transistors as the pass transistors of memory cells 110 to reduce the area occupied by the pass transistors, the coupling capacitance, as well as the interconnect routing complexity, as described below in detail.

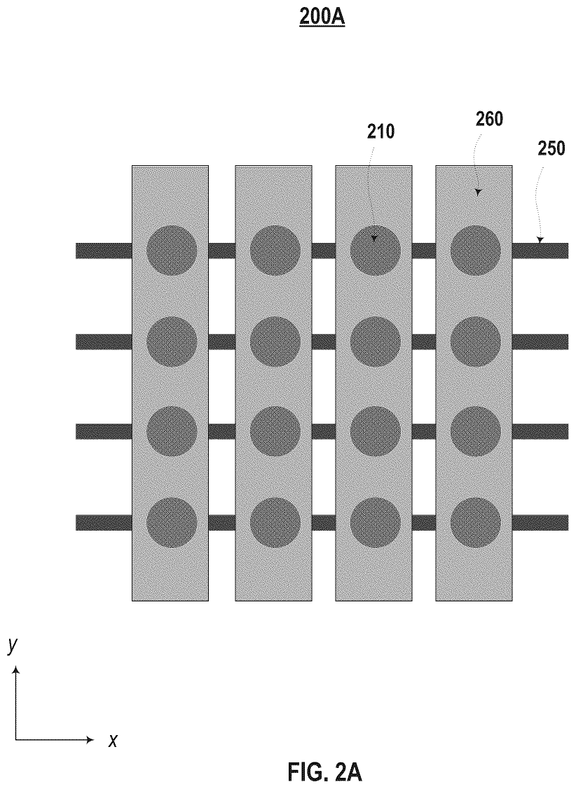

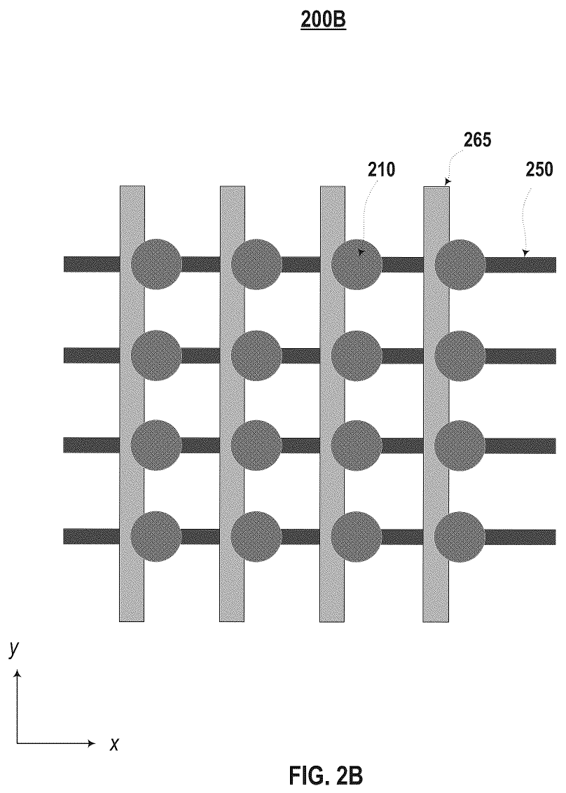

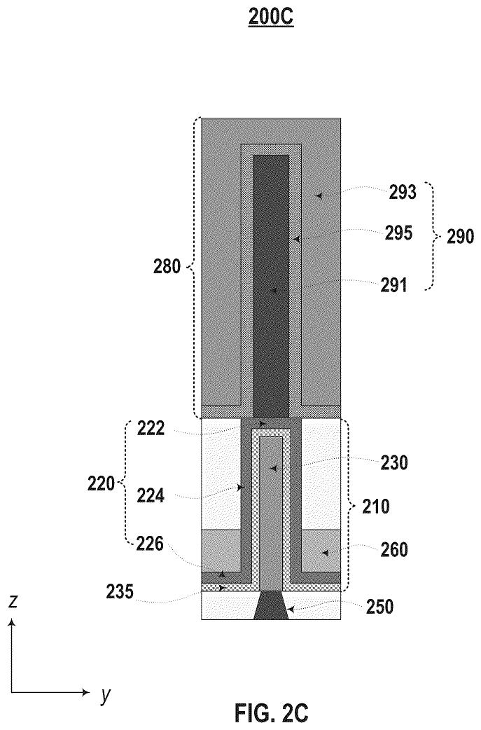

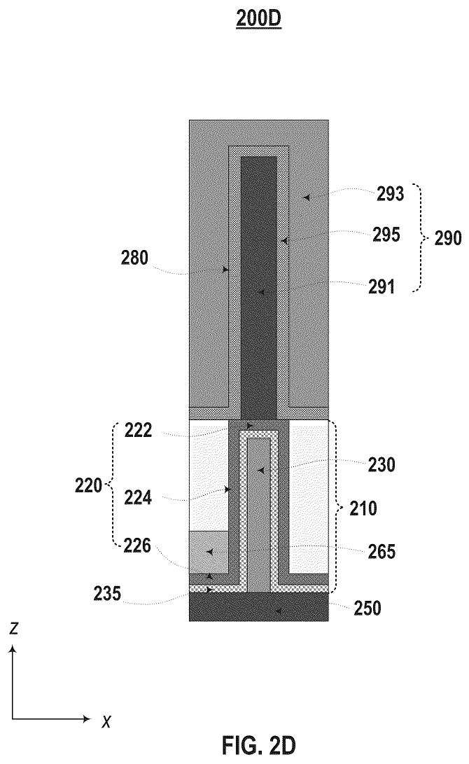

FIGS. 2A and 2B each illustrates a schematic plan view of an array of memory cells each including a channel-all-around (CAA) type vertical transistor in a 3D memory device, according to some implementations of the present disclosure. FIGS. 2C and 2D each illustrates a schematic cross-sectional side view of a memory cell in the 3D memory device shown in FIGS. 2A and 2B, respectively, according to some implementations of the present disclosure. It is noted that FIG. 2C illustrates a cross-sectional side view of a memory cell 200C of the memory cell array 200A along one bit line 260 in the y-z plane, while FIG. 2D illustrates a cross-sectional side view of a memory cell 200D of the memory cell array 200B along one word line 250 in the x-z plane.

As shown in FIG. 2A, the disclosed memory device can include a memory array 200A including a plurality of word lines 250 each extending in a first lateral direction (the x-direction, referred to as the word line direction), and a plurality of bit lines 260 each extending in a second lateral direction perpendicular to the first lateral direction (the y-direction, referred to as the bit line direction). Each bit line 260 laterally surrounds a corresponding column of vertical transistors 210 along the second lateral direction (i.e., the y-direction). It is understood that FIG. 2A does not illustrate cross-section views of the memory device in the same lateral plane, and word lines 250 and bit lines 260 may be formed in different lateral planes for ease of routing, as described below in detail.

As shown in FIG. 2C, in some implementations, each memory cell 200C of the memory array 200A includes a storage unit 280 and a CAA type vertical transistor 210 having a semiconductor layer 220 and a gate electrode 230 surrounded by the semiconductor layer 200. The vertical transistor 210 can include a semiconductor layer 220 having a leakage value lower than a pico-ampere. In some implementations, the leakage value of the semiconductor layer 220 is lower than an intrinsic leakage value of monocrystalline silicon. In some implementations, a material of the semiconductor layer 220 can be a metal oxide semiconductor material, such as indium gallium zinc oxide (IGZO). In the CAA type vertical channel transistors 210, the semiconductor layer 220 can include a first lateral semiconductor portion 222 used as a source, a vertical semiconductor portion 224 used as a channel, and a second lateral semiconductor portion 226 used as a drain.

The vertical semiconductor portion 224 can extend in the vertical direction (i.e., z-direction) perpendicular to the first and second lateral directions. The first lateral semiconductor portion 222 can extend in the lateral plane (i.e., x-y plane) and in contact with the storage unit 280. It is understood that first lateral semiconductor portion 222 may have any suitable shape, such as square shape, a rectangular shape (or a trapezoidal shape), a circular shape, a partial circular shape, an oval shape, a partial oval shape, or any other suitable shapes. The bit line 260 laterally surrounds a lower sidewall of the vertical semiconductor portion 224 and in contact with a second lateral semiconductor portion 226.

The vertical transistor 210 further includes a gate electrode 230 extending along the vertical direction (i.e., z-direction) and laterally surrounded by the vertical semiconductor portion 224. The gate electrode 230 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 230 may include doped polysilicon, i.e., a gate poly. In some implementations, gate electrode 230 includes multiple conductive layers, such as a W layer over a TiN layer.

In some implementations, gate dielectric layer 235 is located between the semiconductor layer 220 and the gate electrode 230. A word line 250 can be in contact with the gate electrodes 230 of a row of vertical transistors 210 along the first lateral direction (i.e., x-direction). Gate dielectric layer 235 can include any suitable dielectric materials, such as silicon oxide, silicon nitride, silicon oxynitride, or high-k dielectrics. For example, gate dielectric layer 235 may include silicon oxide, i.e., gate oxide.

In some implementations, storage unit 280 can include any devices that can store binary data (e.g., 0 and 1), including but not limited to, capacitors for DRAM cells, and PCM elements for PCM cells. In some implementations, each vertical transistor 210 controls the selection and/or the state switch of the respective storage unit 280 coupled to vertical transistor 210. In some implementations, the storage unit 280 includes a capacitor 290. It is understood that the capacitor 290 may include any suitable structure and configuration, such as a planar capacitor, a stack capacitor, a multi-fins capacitor, a cylinder capacitor, a trench capacitor, or a substrate-plate capacitor.

As shown in FIG. 2C, capacitor 290 includes a first electrode 291 coupled with the source/drain of vertical transistor 210. The capacitor can also include a second electrode 293 separated from the vertical transistor 210 and a capacitor dielectric 295 between the first electrode 291 and the second electrode 293. As shown, capacitor 290 can be a vertical capacitor in which two electrodes 291, 293, and the capacitor dielectric 295 in between are stacked vertically (in the z-direction). In some implementations, each first electrode 291 can be coupled to the source (i.e., the first lateral semiconductor portion 222 of semiconductor layer 220) of a respective vertical transistor 210 in the same DRAM cell, while all second electrodes 293 can be parts of a common plate coupled to the ground, e.g., a common ground. In some implementations, the capacitor dielectric 295 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the two electrodes 291, 293 can include conductive materials including, but not limited to, W, Co, Cu, Al, TiN, TaN, polysilicon, silicides, or any combination thereof.

As shown in FIG. 2B, the disclosed memory device can include a memory array 200B including a plurality of word lines 250 each extending in a first lateral direction (the x-direction, referred to as the word line direction), and a plurality of bit lines 265 each extending in a second lateral direction perpendicular to the first lateral direction (the y-direction, referred to as the bit line direction). Each bit line 265 is located at a side of a corresponding column of vertical transistors 210 along the second lateral direction. It is understood that FIG. 2B does not illustrate cross-section views of the memory device in the same lateral plane, and word lines 250 and bit lines 265 may be formed in different lateral planes for ease of routing, as described below in detail.

As shown in FIG. 2D, in some implementations, each memory cell 200D of the memory array 200B includes a storage unit 280 and a CAA type vertical transistor 210 having a semiconductor layer 220 and a gate electrode 230 surrounded by the semiconductor layer 220. The vertical transistor 210 can include a semiconductor layer 220 having a leakage value lower than a pico-ampere. In some implementations, the leakage value of the semiconductor layer 220 is lower than an intrinsic leakage value of monocrystalline silicon. In some implementations, a material of the semiconductor layer 220 can be a metal oxide semiconductor material, such as IGZO. In CAA type vertical channel transistors 210, the semiconductor layer 220 can include a first lateral semiconductor portion 222 used as a source, a vertical semiconductor portion 224 used as a channel, and a second lateral semiconductor portion 226 used as a drain.

The vertical semiconductor portion 224 can extend in the vertical direction (i.e., z-direction) perpendicular to the first and second lateral directions. The first lateral semiconductor portion 222 can extend in the lateral plane (i.e., x-y plane) and in contact with the storage unit 280. It is understood that first lateral semiconductor portion 222 may have any suitable shape, such as square shape, a rectangular shape (or a trapezoidal shape), a circular shape, a partial circular shape, an oval shape, a partial oval shape, or any other suitable shapes. The bit line 265 partially surrounds a lower sidewall of the vertical semiconductor portion 224 and in contact with a portion of the second lateral semiconductor portion 226.

The vertical transistor 210 further includes a gate electrode 230 extending along the vertical direction (i.e., z-direction) and laterally surrounded by the vertical semiconductor portion 224. The gate electrode 230 can include any suitable conductive materials, such as polysilicon, metals (e.g., W, Cu, Al, etc.), metal compounds (e.g., TiN, TaN, etc.), or silicides. For example, gate electrode 230 may include doped polysilicon, i.e., a gate poly. In some implementations, gate electrode 230 includes multiple conductive layers, such as a W layer over a TiN layer.

In some implementations, gate dielectric layer 235 is located between the semiconductor layer 220 and the gate electrode 230. A word line 250 can be in contact with the gate electrodes 230 of a row of vertical transistors 210 along the first lateral direction (i.e., x-direction). Gate dielectric layer 235 can include any suitable dielectric materials, such as silicon oxide, silicon nitride, silicon oxynitride, or high-k dielectrics. For example, gate dielectric layer 235 may include silicon oxide, i.e., gate oxide.

In some implementations, storage unit 280 can include any devices that can store binary data (e.g., 0 and 1), including but not limited to, capacitors for DRAM cells, and PCM elements for PCM cells. In some implementations, each vertical transistor 210 controls the selection and/or the state switch of the respective storage unit 280 coupled to vertical transistor 210. In some implementations, the storage unit 280 includes a capacitor 290. It is understood that the capacitor 290 may include any suitable structure and configuration, such as a planar capacitor, a stack capacitor, a multi-fins capacitor, a cylinder capacitor, a trench capacitor, or a substrate-plate capacitor.

As shown in FIG. 2D, capacitor 290 includes a first electrode 291 coupled with the source/drain of vertical transistor 210. The capacitor can also include a second electrode 293 separated from the vertical transistor 210 and a capacitor dielectric 295 between the first electrode 291 and the second electrode 293. As shown, capacitor 290 can be a vertical capacitor in which two electrodes 291, 293, and the capacitor dielectric 295 in between are stacked vertically (in the z-direction). In some implementations, each first electrode 291 can be coupled to the source (i.e., the first lateral semiconductor portion 222 of semiconductor layer 220) of a respective vertical transistor 210 in the same DRAM cell, while all second electrodes 293 can be parts of a common plate coupled to the ground, e.g., a common ground. In some implementations, the capacitor dielectric 295 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the two electrodes 291, 293 can include conductive materials including, but not limited to, W, Co, Cu, Al, TiN, TaN, polysilicon, silicides, or any combination thereof.

In some implementations, one or more peripheral circuits (not shown) can be coupled to the memory cell array 200A/200B through bit lines 260/265, word lines 250, and any other suitable metal wirings. It is noted that the one or more peripheral circuits can include any suitable circuits for facilitating the operations of memory cell array 200A/200B by applying and sensing voltage signals and/or current signals through word lines 250 and bit lines 260/265 to and from each vertical transistor 210. The one or more peripheral circuits can include various types of peripheral circuits formed using CMOS technologies.

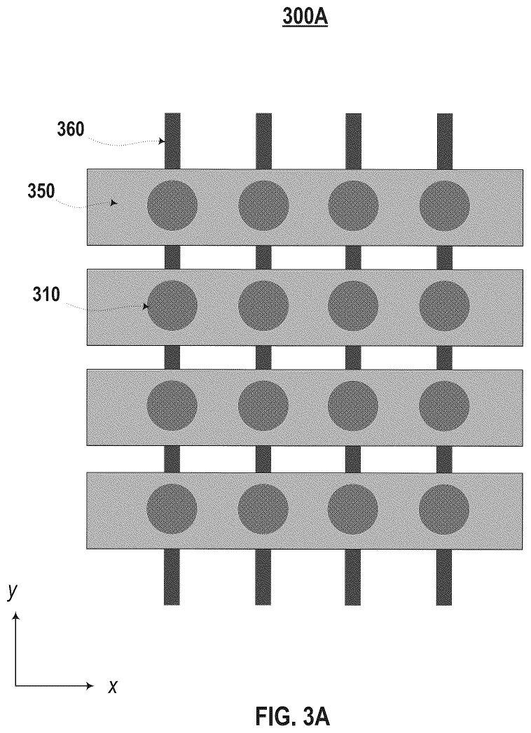

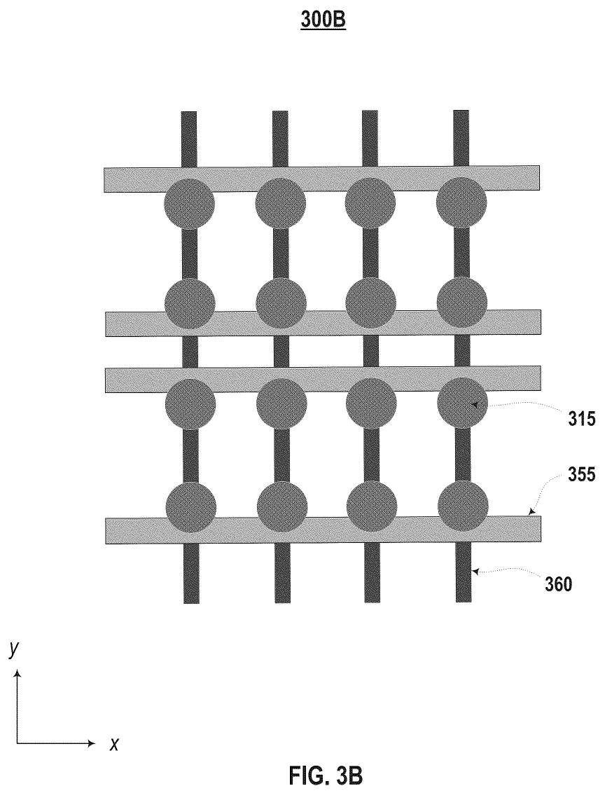

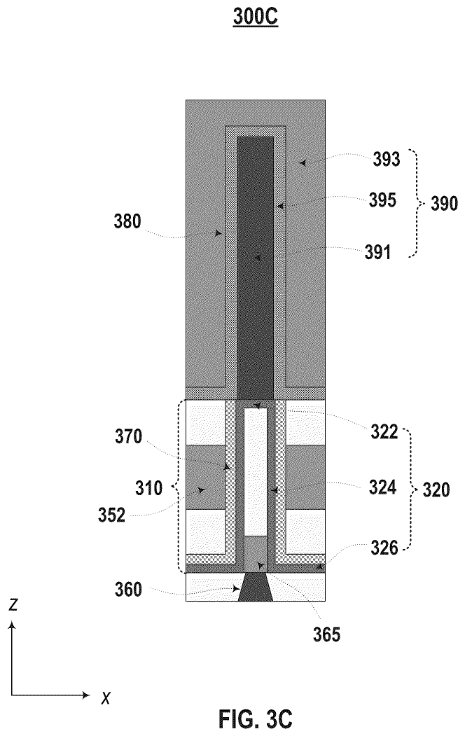

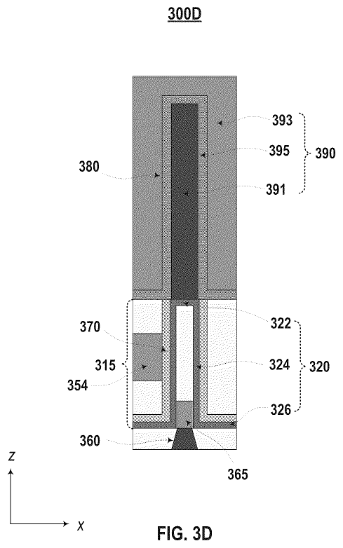

FIG. 3A illustrates a schematic plan view of an array of memory cells each including a gate-all-around (GAA) type vertical transistor in a 3D memory device, according to some implementations of the present disclosure. FIG. 3C illustrates a schematic cross-sectional side view of a memory cell in the 3D memory device shown in FIG. 3A, according to some implementations of the present disclosure. FIG. 3B illustrates a schematic plan view of an array of memory cells each including a gate-partially-around (GPA) type vertical transistor in a 3D memory device, according to some implementations of the present disclosure. FIG. 3D illustrates a schematic cross-sectional side view of a memory cell in the 3D memory device shown in FIG. 3B, according to some implementations of the present disclosure. It is noted that FIGS. 3C and 3D each illustrates a cross-sectional side view of a memory cell 300C/300D of the memory cell array 300A/300B along one bit line 360 in the y-z plane.

As shown in FIG. 3A, the disclosed memory device can include a memory array 300A including a plurality of word lines 350 each extending in a first lateral direction (the x-direction, referred to as the word line direction), and a plurality of bit lines 360 each extending in a second lateral direction perpendicular to the first lateral direction (the y-direction, referred to as the bit line direction). Each word line 350 laterally surrounds a corresponding row of vertical transistors 310 along the first lateral direction (i.e., the x-direction). It is understood that FIG. 3A does not illustrate cross-section views of the memory device in the same lateral plane, and word lines 350 and bit lines 360 may be formed in different lateral planes for ease of routing, as described below in detail.

As shown in FIG. 3C, in some implementations, each memory cell 300C of the memory array 300A includes a storage unit 380 and a GAA type vertical transistor 310 having a semiconductor layer 320 and a gate structure 352 laterally surrounding the semiconductor layer 320. The vertical transistor 310 can include a semiconductor layer 320 having a leakage value lower than a pico-ampere. In some implementations, the leakage value of the semiconductor layer 320 is lower than an intrinsic leakage value of monocrystalline silicon. In some implementations, a material of the semiconductor layer 320 can be a metal oxide semiconductor material, such as IGZO. In the GAA type vertical channel transistors 310, the semiconductor layer 320 can include a first lateral semiconductor portion 322 used as a source, a vertical semiconductor portion 324 used as a channel, and a second lateral semiconductor portion 326 used as a drain.

The vertical semiconductor portion 324 can extend in the vertical direction (i.e., z-direction) perpendicular to the first and second lateral directions. The first lateral semiconductor portion 322 can extend in the lateral plane (i.e., x-y plane) and in contact with the storage unit 380. It is understood that first lateral semiconductor portion 322 may have any suitable shape, such as square shape, a rectangular shape (or a trapezoidal shape), a circular shape, a partial circular shape, an oval shape, a partial oval shape, or any other suitable shapes.

The GAA vertical transistor 310 further includes a gate electrode 352 laterally surrounding a middle portion of the vertical semiconductor portion 324 of the semiconductor layer 320. The gate electrode 352 can include any suitable conductive materials, such as polysilicon, metals (e.g., W, Cu, Al, etc.), metal compounds (e.g., TiN, TaN, etc.), or silicides. For example, gate electrode 352 may include doped polysilicon, i.e., a gate poly. In some implementations, gate electrode 352 includes multiple conductive layers, such as a W layer over a TiN layer. As shown in FIG. 3A, the gate electrodes 352 of adjacent vertical transistors 310 along the first lateral direction (i.e., x-direction) are continuous, e.g., parts of a continuous conductive layer having the gate electrodes 352. That is, multiple gate electrodes 352 of a row of vertical transistors 310 can be connected with each other and extending along the first lateral direction to form a word line 350 of the row of vertical transistors 310. In some implementations, gate dielectric layer 370 is located between the semiconductor layer 320 and the gate electrode 352. Gate dielectric layer 370 can include any suitable dielectric materials, such as silicon oxide, silicon nitride, silicon oxynitride, or high-k dielectrics. For example, gate dielectric layer 370 may include silicon oxide, i.e., gate oxide.

As shown in FIG. 3C, bit line contact 365 is in contact with and surrounded by a lower portion of the vertical semiconductor portion 324. The bit line contact 365 can be heavily doped semiconductor material with any suitable P-type dopants, such as boron (B) or Gallium (Ga), or any suitable N-type dopants, such as phosphorus (P) or arsenic (As). In some implementations as shown in FIGS. 3A and 3C, each bit line 360 can extend along the second lateral direction (i.e., y-direction) and in contact with the bit line contacts 365 of a column of vertical transistors 310 along the second lateral direction (i.e., y-direction). In some implementations, bit line 360 can include a silicide line (not shown) including any suitable metal silicide material, and a metal line (not shown) including any suitable metal material, such as W, Cu, Al, etc.

In some implementations, the storage unit 380 can include any devices that can store binary data (e.g., 0 and 1), including but not limited to, capacitors for DRAM cells, and PCM elements for PCM cells. In some implementations, each vertical transistor 310 controls the selection and/or the state switch of the respective storage unit 380 coupled to vertical transistor 310. In some implementations, the storage unit 380 includes a capacitor 390. It is understood that the capacitor 390 may include any suitable structure and configuration, such as a planar capacitor, a stack capacitor, a multi-fins capacitor, a cylinder capacitor, a trench capacitor, or a substrate-plate capacitor.

As shown in FIG. 3C, capacitor 390 includes a first electrode 393 coupled with the source/drain of vertical transistor 310. The capacitor can also include a second electrode 393 separated from the vertical transistor 310 and a capacitor dielectric 395 between the first electrode 391 and the second electrode 393. As shown, capacitor 390 can be a vertical capacitor in which two electrodes 391, 393, and the capacitor dielectric 395 in between are stacked vertically (in the z-direction). In some implementations, each first electrode 391 can be coupled to the source (i.e., the first lateral semiconductor portion 322 of semiconductor layer 320) of a respective vertical transistor 310 in the same DRAM cell, while all second electrodes 393 can be parts of a common plate coupled to the ground, e.g., a common ground. In some implementations, the capacitor dielectric 395 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the two electrodes 291, 293 can include conductive materials including, but not limited to, W, Co, Cu, Al, TiN, TaN, polysilicon, silicides, or any combination thereof.

It is noted that the disclosed memory device can include single-gate transistors 315 as shown in FIGS. 3B and 3D. That is, the word line 335 or gate electrode 354 may be in contact with a single side of semiconductor layer 320. In some other implementations not shown, the disclosed memory device can include multi-gate vertical transistors, such as double-gate vertical transistors (i.e., dual-side gate vertical transistors), tri-gate vertical transistors (i.e., tri-side gate vertical transistors), etc.

As shown in FIG. 3B, the disclosed memory device can include a memory array 300B including a plurality of word lines 355 each extending in a first lateral direction (the x-direction, referred to as the word line direction), and a plurality of bit lines 360 each extending in a second lateral direction perpendicular to the first lateral direction (the y-direction, referred to as the bit line direction). Each word line 355 is located at a side of a corresponding row of vertical transistors 315 along the first lateral direction (i.e., the x-direction). It is understood that FIG. 3B does not illustrate cross-section views of the memory device in the same lateral plane, and word lines 355 and bit lines 360 may be formed in different lateral planes for ease of routing, as described below in detail.

As shown in FIG. 3D, in some implementations, each memory cell 300D of the memory array 300B includes a storage unit 380 and a single gate vertical transistor 315 having a semiconductor layer 320 and a gate electrode 354 partially surrounding the semiconductor layer 320. The vertical transistor 315 can include a semiconductor layer 320 having a leakage value lower than a pico-ampere. In some implementations, the leakage value of the semiconductor layer 320 is lower than an intrinsic leakage value of monocrystalline silicon. In some implementations, a material of the semiconductor layer 320 can be a metal oxide semiconductor material, such as IGZO. In the vertical channel transistors 315, the semiconductor layer 320 can include a first lateral semiconductor portion 322 used as a source, a vertical semiconductor portion 324 used as a channel, and a second lateral semiconductor portion 326 used as a drain.

The vertical semiconductor portion 324 can extend in the vertical direction (i.e., z-direction) perpendicular to the first and second lateral directions. The first lateral semiconductor portion 322 can extend in the lateral plane (i.e., x-y plane) and in contact with the storage unit 380. It is understood that first lateral semiconductor portion 322 may have any suitable shape, such as square shape, a rectangular shape (or a trapezoidal shape), a circular shape, a partial circular shape, an oval shape, a partial oval shape, or any other suitable shapes.

The single gate vertical transistor 315 further includes a gate electrode 354 located at a side of a middle portion of the vertical semiconductor portion 324 of the semiconductor layer 320. The gate electrode 354 can include any suitable conductive materials, such as polysilicon, metals (e.g., W, Cu, Al, etc.), metal compounds (e.g., TiN, TaN, etc.), or silicides. For example, gate electrode 354 may include doped polysilicon, i.e., a gate poly. In some implementations, gate electrode 354 includes multiple conductive layers, such as a W layer over a TiN layer. As shown in FIG. 3B, the gate electrodes 354 of adjacent vertical transistors 315 along the first lateral direction (i.e., x-direction) are continuous, e.g., parts of a continuous conductive layer having the gate electrodes 354. That is, multiple gate electrodes 354 of a row of vertical transistors 315 can be connected with each other and extending along the first lateral direction to form a word line 355 of the row of vertical transistors 315. In some implementations, gate dielectric layer 370 is located between the semiconductor layer 320 and the gate electrode 354. Gate dielectric layer 370 can include any suitable dielectric materials, such as silicon oxide, silicon nitride, silicon oxynitride, or high-k dielectrics. For example, gate dielectric layer 370 may include silicon oxide, i.e., gate oxide.

As shown in FIG. 3D, bit line contact 365 is in contact with and surrounded by a lower portion of the vertical semiconductor portion 324. The bit line contact 365 can be heavily doped semiconductor material with any suitable P-type dopants, such as boron (B) or Gallium (Ga), or any suitable N-type dopants, such as phosphorus (P) or arsenic (As). In some implementations as shown in FIGS. 3B and 3D, each bit line 360 can extend along the second lateral direction (i.e., y-direction) and in contact with the bit line contacts 365 of a column of vertical transistors 315 along the second lateral direction (i.e., y-direction). In some implementations, bit line 360 can include a silicide line (not shown) including any suitable metal silicide material, and a metal line (not shown) including any suitable metal material, such as W, Cu, Al, etc.

In some implementations, the storage unit 380 can include any devices that can store binary data (e.g., 0 and 1), including but not limited to, capacitors for DRAM cells, and PCM elements for PCM cells. In some implementations, each vertical transistor 315 controls the selection and/or the state switch of the respective storage unit 380 coupled to vertical transistor 315. In some implementations, the storage unit 380 includes a capacitor 390. It is understood that the capacitor 390 may include any suitable structure and configuration, such as a planar capacitor, a stack capacitor, a multi-fins capacitor, a cylinder capacitor, a trench capacitor, or a substrate-plate capacitor.

As shown in FIG. 3D, capacitor 390 includes a first electrode 393 coupled with the source/drain of vertical transistor 315. The capacitor can also include a second electrode 393 separated from the vertical transistor 315 and a capacitor dielectric 395 between the first electrode 391 and the second electrode 393. As shown, capacitor 390 can be a vertical capacitor in which two electrodes 391, 393, and the capacitor dielectric 395 in between are stacked vertically (in the z-direction). In some implementations, each first electrode 391 can be coupled to the source (i.e., the first lateral semiconductor portion 322 of semiconductor layer 320) of a respective vertical transistor 315 in the same DRAM cell, while all second electrodes 393 can be parts of a common plate coupled to the ground, e.g., a common ground. In some implementations, the capacitor dielectric 395 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the two electrodes 291, 293 can include conductive materials including, but not limited to, W, Co, Cu, Al, TiN, TaN, polysilicon, silicides, or any combination thereof.

In some implementations, one or more peripheral circuits (not shown) can be coupled to the memory cell array 300A/300B through bit lines 360, word lines 350/355, and any other suitable metal wirings. It is noted that the one or more peripheral circuits can include any suitable circuits for facilitating the operations of memory cell array 300A/300B by applying and sensing voltage signals and/or current signals through word lines 350/355 and bit lines 360 to and from each memory cell 310/315. The one or more peripheral circuits can include various types of peripheral circuits formed using CMOS technologies.

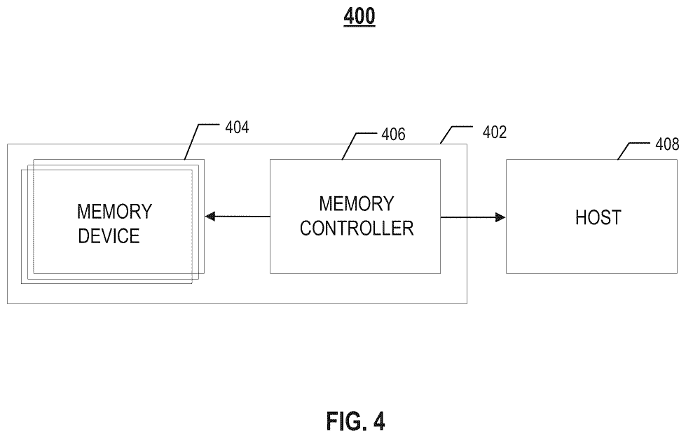

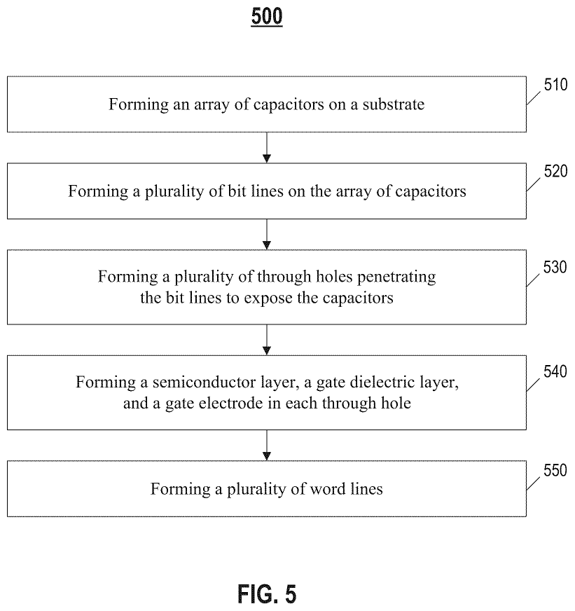

FIG. 4 illustrates a block diagram of a system 400 having a memory device, according to some implementations of the present disclosure. System 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, system 400 can include a host 408 and a memory system 402 having one or more memory devices 404 and a memory controller 406. Host 408 can be a processor of an electronic device, such as a central processing unit (CPU), or a system-on-chip (SoC), such as an application processor (AP). Host 408 can be configured to send or receive the data to or from memory devices 404. Memory device 404 can be any memory devices disclosed herein, such as memory device 100. In some implementations, memory device 404 includes an array of memory cells shown in 200A/200B/300A/300B each including a vertical transistor, as described above in detail.

Memory controller 406 is coupled to memory device 404 and host 408 and is configured to control memory device 404, according to some implementations. Memory controller 406 can manage the data stored in memory device 404 and communicate with host 408. Memory controller 406 can be configured to control operations of memory device 404, such as read, write, and refresh operations. Memory controller 406 can also be configured to manage various functions with respect to the data stored or to be stored in memory device 404 including, but not limited to refresh and timing control, command/request translation, buffer and schedule, and power management. In some implementations, memory controller 406 is further configured to determine the maximum memory capacity that the computer system can use, the number of memory banks, memory type and speed, memory particle data depth and data width, and other important parameters. Any other suitable functions may be performed by memory controller 406 as well. Memory controller 406 can communicate with an external device (e.g., host 408) according to a particular communication protocol. For example, memory controller 406 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

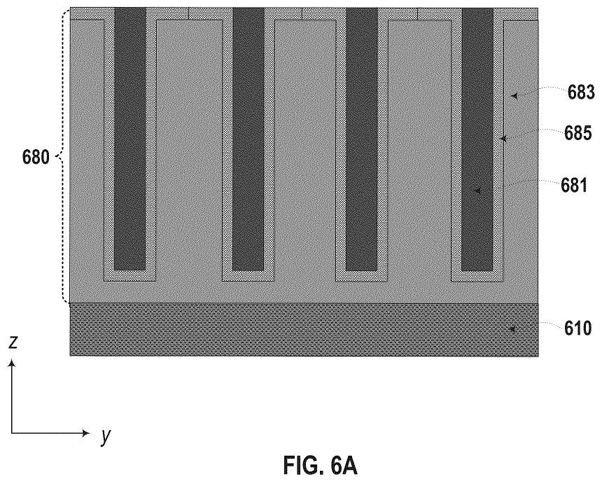

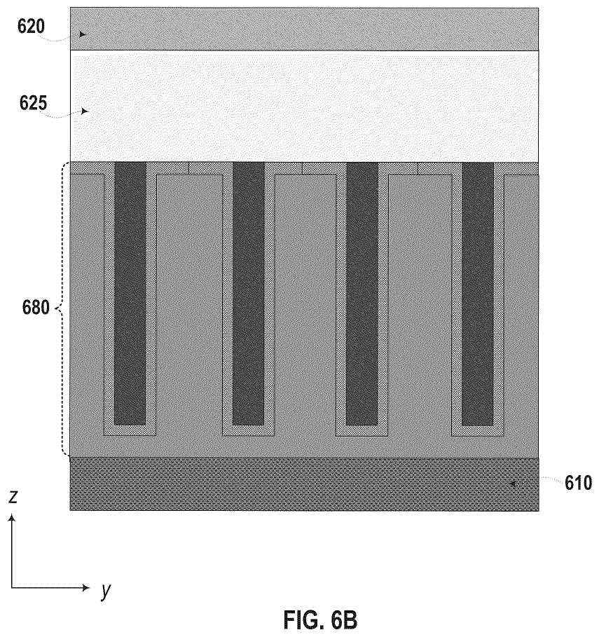

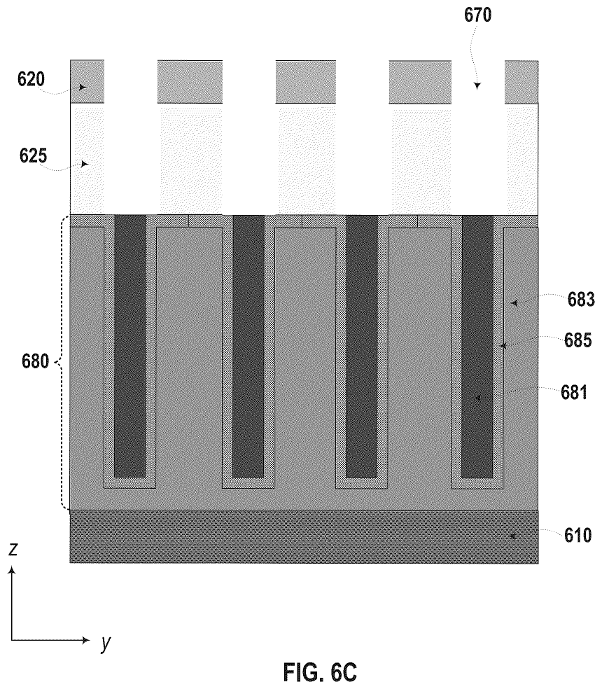

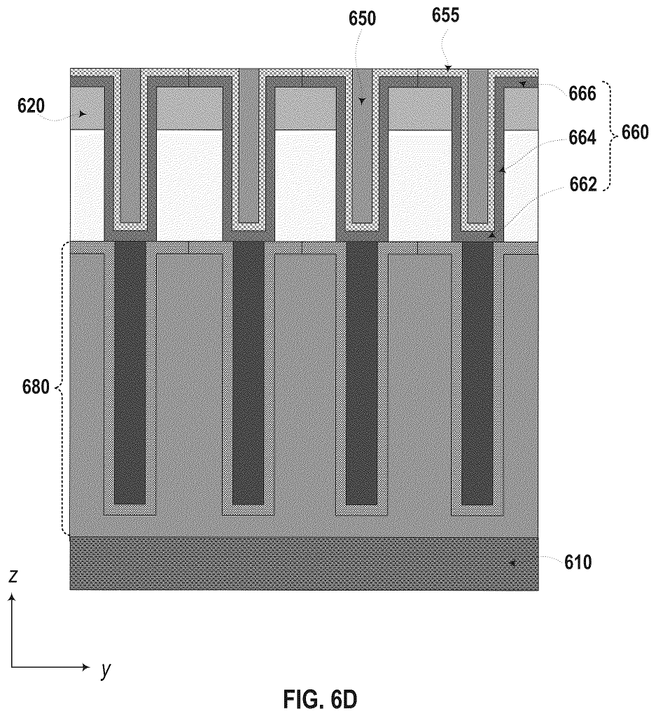

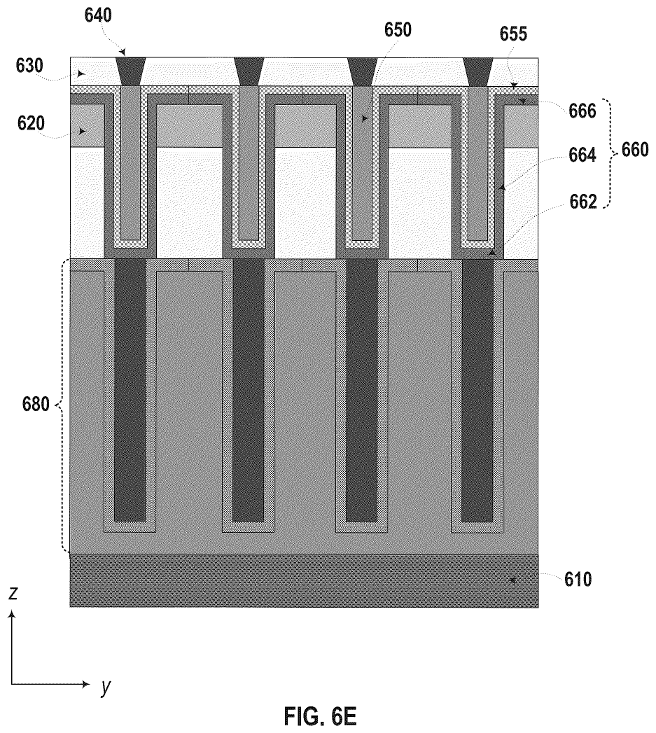

FIG. 5 illustrates a flowchart of a fabricating method 500 for forming a 3D memory device including vertical transistors, such as memory array 200A described above in connection with FIG. 2A, according to some implementations of the present disclosure. FIGS. 6A-6E illustrate schematic side cross-sectional views of a 3D memory device at certain fabricating stages of the method 500 shown in FIG. 5, according to various implementations of the present disclosure. It is understood that the operations shown in method 500 are not exhaustive and that other operations can be performed as well before, after, or between any of the illustrated operations. Further, some of the operations may be performed simultaneously, or in a different order than shown in FIG. 5.

As shown in FIG. 5, method 500 can start at operation 510, in which an array of capacitors can be formed on a substrate. FIG. 6A illustrates a schematic side cross-sectional view of the 3D memory device in y-z plane after operation 510 of method 500.

As shown in FIG. 6A, an array of capacitors 680 can be formed on a substrate 610. In some implementations, the substrate 610 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In such implementations, the array of capacitors 680 can be formed directly on the semiconductor substrate 610, and the transistor can be formed on a front side of the array of capacitors 680 in subsequent processes. In some other implementations, the substrate 610 can be a carrier substrate, which can include any suitable semiconductor materials, or an electrically non-conductive material, such as a glass, a plastic, or a sapphire wafer. In such implementations, the array of capacitors 680 can be formed directly on another semiconductor substrate, and the carrier substrate 610 can be formed on a front side of the array of capacitors 680. After flipping over the structure and removing the semiconductor substrate, the transistor can be formed on a back side of the array of capacitors 680 in subsequent processes.

The array of capacitors 680 can include a common second electrode 683, a plurality of first electrode 681, and a capacitor dielectric layer 685 between the first electrodes 681 and the common second electrode 683. As shown, the array of capacitors 680 can be an array. In some implementations, the first electrodes 681 and/or the common second electrode 683 can include conductive materials including, but not limited to, W, Co, Cu, Al, TiN, TaN, polysilicon, silicides, or any combination thereof. In some implementations, the capacitor dielectric layer 685 includes dielectric materials, such as silicon oxide, silicon nitride, or high-k dielectrics including, but not limited to, Al₂O₃, HfO₂, Ta₂O₅, ZrO₂, TiO₂, or any combination thereof.

In some implementations, the array of capacitors 680 can be formed by a series of fabricating processes including thin film deposition processes (e.g., chemical vapor deposition (CVD), physical vapor deposition (PVD), atomic layer deposition (ALD), etc.) and patterning processes (e.g., photoetching, dry etching, wet etching, cleaning, chemical mechanical polishing (CMP), etc. It is noted that, the fabricating processes and/or orders of forming the first electrodes 681, the common second electrode 683, and the capacitor dielectric layer 685 can be varied depending on a front side process or a back side process.

As shown in FIG. 5, method 500 can proceed to operation 520, in which a plurality of bit lines can be formed on the array of capacitors. FIG. 6B illustrates a schematic side cross-sectional view of the 3D memory device in y-z plane after operation 520 of method 500.

In some implementations as shown in FIG. 6B, a first dielectric layer 625 can be formed on the array of capacitors 680, a conductive layer can be formed on the first dielectric layer 626. The conductive layer can be patterned to form a plurality of bit lines 620, parallelly arranged in the first lateral direction (x-direction), each extending along the second lateral direction (y-direction).

As shown in FIG. 5, method 500 can proceed to operation 530, in which a plurality of through holes can be formed, each through hole penetrating a corresponding bit line and the dielectric layer to expose a corresponding one of the plurality of capacitors. FIG. 6C illustrates a schematic side cross-sectional view of the 3D memory device in y-z plane after operation 530 of method 500.

As shown in FIG. 6C, along each bit line 620, a plurality of through holes 670 can be formed by using any suitable etching processes. Each through hole 670 can penetrate the bit line 620 and the first dielectric layer 625 below the bit line, and expose the first electrode 681 of a corresponding capacitor 680.

As shown in FIG. 5, method 500 can proceed to operation 540, in which a semiconductor layer, a gate dielectric layer, and a gate electrode can be formed in each through hole. FIG. 6D illustrates a schematic side cross-sectional view of the 3D memory device in y-z plane after operation 540 of method 500. The semiconductor layer 660, the gate dielectric layer 655, and the gate electrode 650 can be formed by multiple thin film deposition processes (e.g., CVD, PVD, ALD, etc.) and one or more CMP processes.

As shown in FIG. 6D, semiconductor layer 660 can be formed to cover the sidewall and the bottom of each through hole 670. The semiconductor layer 660 can have a leakage value lower than a pico-ampere. In some implementations, the leakage value of the semiconductor layer 660 is lower than an intrinsic leakage value of monocrystalline silicon. In some implementations, a material of the semiconductor layer 660 can be a metal oxide semiconductor material, such as IGZO. In some implementations, the semiconductor layer 660 can include a first lateral semiconductor portion 662 located at the bottom of the through hole 670 and in contact with the first electrode 681 of a corresponding capacitor 680, a vertical semiconductor portion 664 on the sidewall of the through hole 670, and a second lateral semiconductor portion 666 located outside of the through hole 670.

Gate dielectric layer 655 can be formed to cover the semiconductor layer 660. Gate dielectric layer 655 can include any suitable dielectric materials, such as silicon oxide, silicon nitride, silicon oxynitride, or high-k dielectrics. For example, gate dielectric layer 655 may include silicon oxide, i.e., gate oxide. Gate electrode 650 can be formed to fill the through hole 670. The gate electrode 650 can include any suitable conductive materials, such as polysilicon, metals (e.g., W, Cu, Al, etc.), metal compounds (e.g., TiN, TaN, etc.), or silicides. For example, gate electrode 650 may include doped polysilicon, i.e., a gate poly. In some implementations, gate electrode 650 includes multiple conductive layers, such as a W layer over a TiN layer.

As shown in FIG. 5, method 500 can proceed to operation 550, in which a plurality of word lines can be formed. The word lines can extend in parallel along the first lateral direction and each in contact with the gate electrodes of a row of vertical transistors. FIG. 6E illustrates a schematic side cross-sectional view of the 3D memory device in y-z plane after operation 550 of method 500.

As shown in FIG. 6E, forming the word lines 640 can include forming a second dielectric layer 630 to cover the gate dielectric layer 655 and the gate electrodes 650, patterning the second dielectric layer 630 to form a plurality of trenches (not shown), and depositing a conductive material in the trenches to form the word lines 640. The plurality of word lines 640 are arranged in parallel along the second lateral direction (y-direction), and each extend along the first lateral direction (x-direction) and coupled with the gate electrodes of a row of vertical transistors in the first lateral direction.

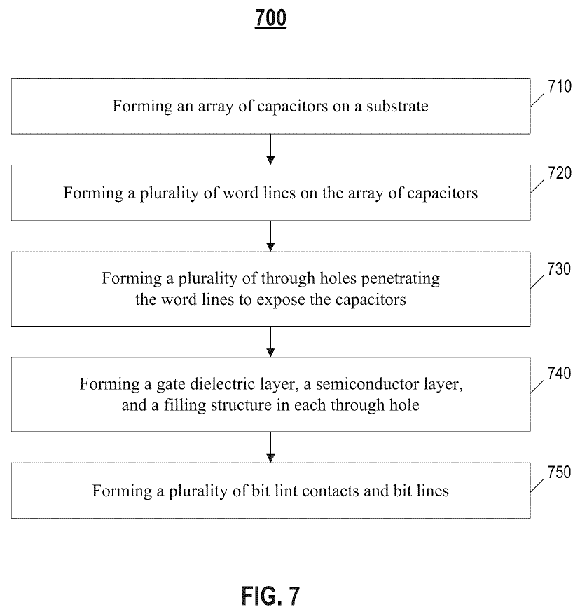

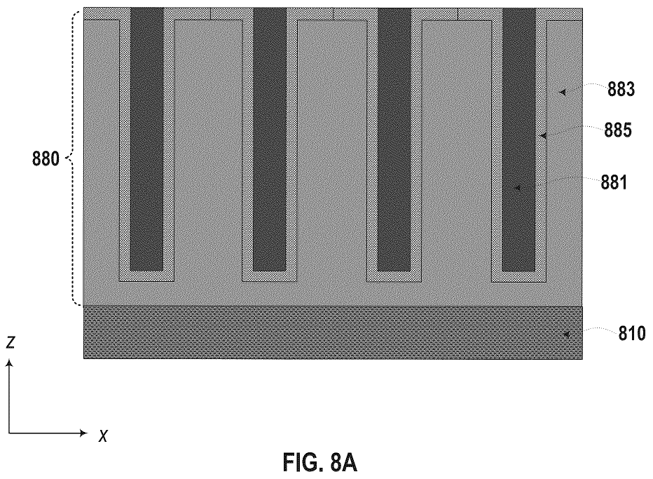

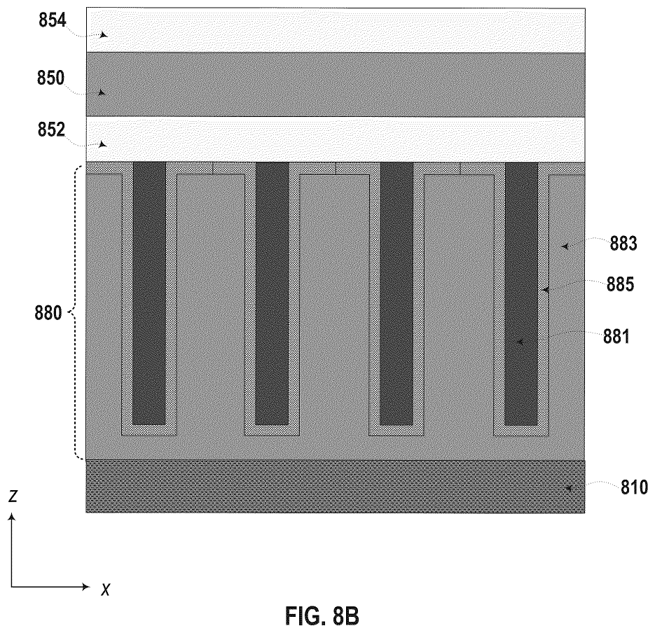

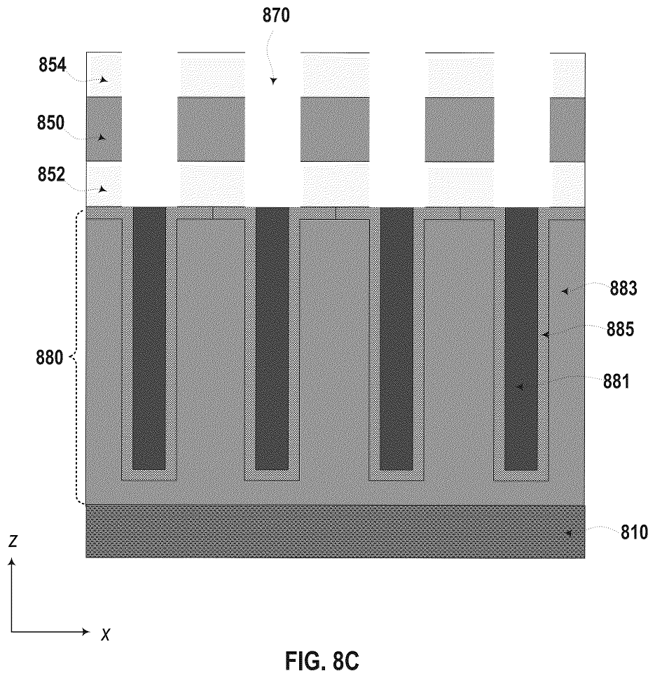

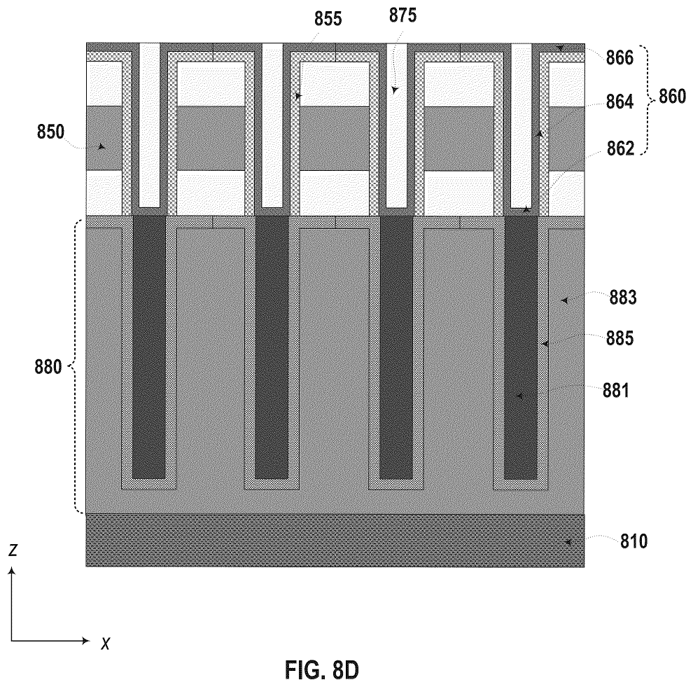

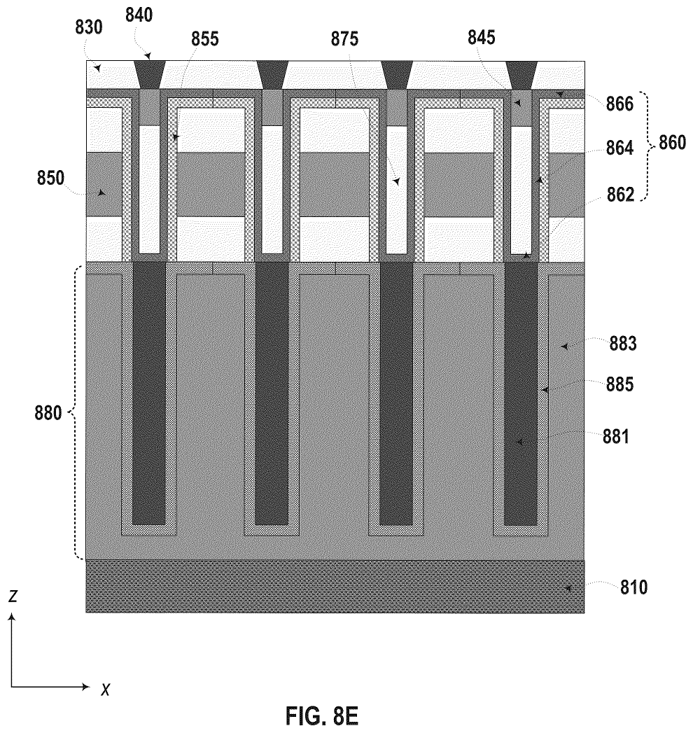

FIG. 7 illustrates a flowchart of a fabricating method 700 for forming a 3D memory device including vertical transistors, such as memory array 300A described above in connection with FIG. 3A, according to some implementations of the present disclosure. FIGS. 8A-8E illustrate schematic side cross-sectional views of a 3D memory device at certain fabricating stages of the method 700 shown in FIG. 7, according to various implementations of the present disclosure. It is understood that the operations shown in method 700 are not exhaustive and that other operations can be performed as well before, after, or between any of the illustrated operations. Further, some of the operations may be performed simultaneously, or in a different order than shown in FIG. 7.

As shown in FIG. 7, method 700 can start at operation 710, in which an array of capacitors can be formed on a substrate. FIG. 8A illustrates a schematic side cross-sectional view of the 3D memory device in x-z plane after operation 710 of method 700.

As shown in FIG. 8A, an array of capacitors 880 can be formed on a substrate 810. In some implementations, the substrate 810 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In such implementations, the array of capacitors 880 can be formed directly on the semiconductor substrate 810, and the transistor can be formed on a front side of the array of capacitors 880 in subsequent processes. In some other implementations, the substrate 810 can be a carrier substrate, which can include any suitable semiconductor materials, or an electrically non-conductive material, such as a glass, a plastic, or a sapphire wafer. In such implementations, the array of capacitors 880 can be formed directly on another semiconductor substrate, and the carrier substrate 810 can be formed on a front side of the array of capacitors 880. After flipping over the structure and removing the semiconductor substrate, the transistor can be formed on a back side of the array of capacitors 880 in subsequent processes.

The array of capacitors 880 can include a common second electrode 883, a plurality of first electrode 881, and a capacitor dielectric layer 885 between the first electrodes 881 and the common second electrode 883. As shown, the array of capacitors 880 can be an array. In some implementations, the first electrodes 881 and/or the common second electrode 883 can include conductive materials including, but not limited to, W, Co, Cu, Al, TiN, TaN, polysilicon, silicides, or any combination thereof. In some implementations, the capacitor dielectric layer 885 includes dielectric materials, such as silicon oxide, silicon nitride, or high-k dielectrics including, but not limited to, Al₂O₃, HfO₂, Ta₂O₅, ZrO₂, TiO₂, or any combination thereof.

In some implementations, the array of capacitors 880 can be formed by a series of fabricating processes including thin film deposition processes (e.g., chemical vapor deposition (CVD), physical vapor deposition (PVD), atomic layer deposition (ALD), etc.) and patterning processes (e.g., photoetching, dry etching, wet etching, cleaning, chemical mechanical polishing (CMP), etc. It is noted that, the fabricating processes and/or orders of forming the first electrodes 881, the common second electrode 883, and the capacitor dielectric layer 885 can be varied depending on a front side process or a back side process.

As shown in FIG. 7, method 700 can proceed to operation 720, in which a plurality of word lines can be formed on the array of capacitors. FIG. 8B illustrates a schematic side cross-sectional view of the 3D memory device in x-z plane after operation 720 of method 700.

In some implementations as shown in FIG. 8B, a first dielectric layer 852 can be formed on the array of capacitors 880, a conductive layer can be formed on the first dielectric layer 852, and a second dielectric layer 854 can be formed on the conductive layer. The conductive layer can be patterned to form a plurality of word lines 850, parallelly arranged in the second lateral direction (y-direction), each extending along the first lateral direction (x-direction). The word lines 850 can include any suitable conductive materials, such as polysilicon, metals (e.g., W, Cu, Al, etc.), metal compounds (e.g., TiN, TaN, etc.), or silicides. For example, word lines 850 may include doped polysilicon. In some implementations, word lines 850 include multiple conductive layers, such as a W layer over a TiN layer.

As shown in FIG. 7, method 700 can proceed to operation 730, in which a plurality of through holes can be formed, each through hole penetrating a corresponding word line and the first and second dielectric layers to expose a corresponding one of the plurality of capacitors. FIG. 8C illustrates a schematic side cross-sectional view of the 3D memory device in x-z plane after operation 730 of method 700.

As shown in FIG. 8C, along each word line 850, a plurality of through holes 870 can be formed by using any suitable etching processes. Each through hole 870 can penetrate the second dielectric layer 854, the corresponding word line 850, and the first dielectric layer 852, and expose the first electrode 881 of a corresponding capacitor 880.

As shown in FIG. 7, method 700 can proceed to operation 740, in which a gate dielectric layer, a semiconductor layer, and a filling structure can be formed in each through hole. FIG. 8D illustrates a schematic side cross-sectional view of the 3D memory device in x-z plane after operation 740 of method 700. The gate dielectric layer 855, the semiconductor layer 860, and the filling structure 875 can be formed by multiple thin film deposition processes (e.g., CVD, PVD, ALD, etc.) and one or more CMP processes.

As shown in FIG. 8D, gate dielectric layer 855 can be formed to cover the sidewall of each through hole 870. Gate dielectric layer 855 can include any suitable dielectric materials, such as silicon oxide, silicon nitride, silicon oxynitride, or high-k dielectrics. For example, gate dielectric layer 855 may include silicon oxide, i.e., gate oxide. Semiconductor layer 860 can be formed to cover the gate dielectric layer 855 and the bottom of each through hole 870. The semiconductor layer 860 can have a leakage value lower than a pico-ampere. In some implementations, the leakage value of the semiconductor layer 860 is lower than an intrinsic leakage value of monocrystalline silicon. In some implementations, a material of the semiconductor layer 860 can be a metal oxide semiconductor material, such as IGZO. In some implementations, the semiconductor layer 860 can include a first lateral semiconductor portion 862 located at the bottom of the through hole 870 and in contact with the first electrode 881 of a corresponding capacitor 880, a vertical semiconductor portion 864 on the sidewall of the through hole 870, and a second lateral semiconductor portion 866 located outside of the through hole 870.

As shown in FIG. 7, method 700 can proceed to operation 750, in which a plurality of bit line contacts and bit lines can be formed. A bit line contact can be formed in the through hole above the filling structure and in contact with an upper portion of the semiconductor layer. The bit lines can extend in parallel along the second lateral direction and each in contact with the bit line contacts of a column of vertical transistors. FIG. 8E illustrates a schematic side cross-sectional view of the 3D memory device in x-z plane after operation 750 of method 700.

As shown in FIG. 8E, forming the bit line contacts 645 can include removing an upper portion of each filling structure 875 by using an etch back process to form a recess in each through hole 870, depositing a conductive material in the recesses in the through holes 870, and a followed CMP process to remove exceed conductive material outside the through holes 870 to form the plurality of bit line contacts 645. Each bit line contact 645 can be in contact with an upper portion of the semiconductor layer 860.

In some implementations, forming the bit lines 840 can include forming a third dielectric layer 830 to cover the top surfaces of the semiconductor layer 860 and the bit line contacts 845, patterning the third dielectric layer 830 to form a plurality of trenches (not shown), and depositing a conductive material in the trenches to form the bit lines 840. The plurality of bit lines 840 are arranged in parallel along the first lateral direction (x-direction), and each extend along the second lateral direction (y-direction) and coupled with the bit line contacts 845 of a column of vertical transistors in the second lateral direction.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations, but should be defined only in accordance with the following claims and their equivalents.

What is claimed is:

1. A semiconductor device, comprising:
a plurality of vertical transistors each comprising:
a semiconductor layer having a leakage value lower than a pico-ampere and comprising a vertical semiconductor portion and at least one lateral semiconductor portion,
a gate dielectric layer comprising a vertical gate dielectric portion on the vertical semiconductor portion and extending in the vertical direction,
a gate electrode on the gate dielectric layer and separated from the semiconductor layer by the gate dielectric layer; and
a plurality of capacitors each coupled with the semiconductor layer of a corresponding one of the plurality of vertical transistors.

2. The semiconductor device of claim 1, wherein:
the gate electrode extends along the vertical direction, and is laterally surrounded by the vertical gate dielectric portion.

3. The semiconductor device of claim 2, wherein:
the vertical gate dielectric portion is laterally surrounded by the vertical semiconductor portion.

4. The semiconductor device of claim 3, wherein:
the gate dielectric layer further comprises a lateral gate dielectric portion in contact with a first end of the gate electrode.

5. The semiconductor device of claim 4, wherein:
a first lateral semiconductor portion is between the lateral gate dielectric portion and one corresponding capacitor.

6. The semiconductor device of claim 2, further comprising:
word lines each extending along a first lateral direction and connected to second ends of the gate electrodes.

7. The semiconductor device of claim 3, further comprising:
bit lines each extending along a second lateral direction and in direct contact with the vertical semiconductor portions.

8. The semiconductor device of claim 7, wherein:
the bit line fully surrounds a sidewall of the vertical semiconductor portion and in contact with a second lateral semiconductor portion.

9. The semiconductor device of claim 7, wherein:
the bit line partially surrounds a sidewall of the vertical metal oxide semiconductor portion and in contact with a second lateral semiconductor portion.

10. The semiconductor device of claim 1, further comprising:
a conductive plug laterally surrounded by the vertical semiconductor portion, and connected to a bit line extending along a second lateral direction,
wherein the vertical semiconductor portion is laterally surrounded by the vertical gate dielectric portion.

11. The semiconductor device of claim 10, wherein:
a word line comprises the gate electrodes connected with each other in a first lateral direction, and at least partially surrounds the vertical gate dielectric portions of the row of the vertical transistors.

12. The semiconductor device of claim 1, wherein:
the leakage value of the semiconductor layer is lower than an intrinsic leakage value of monocrystalline silicon.

13. The semiconductor device of claim 1, wherein:
the semiconductor layer is a metal oxide semiconductor layer.

14. A semiconductor device, comprising:
a plurality of vertical transistors each comprising:
a gate electrode extending in a vertical direction,
a gate dielectric layer laterally surrounding the gate electrode and covering a first end of the gate electrode,
a semiconductor layer laterally surrounding the gate dielectric layer and covering a first end of the gate dielectric layer;
a plurality of capacitors each coupled with the semiconductor layer of a corresponding one of the vertical transistors;
a plurality of word lines each extending along a first lateral direction and coupled with the gate electrodes; and
a plurality of bit lines each extending along a second lateral direction and coupled with the semiconductor layers.

15. The semiconductor device of claim 14, wherein:
the bit line at least partially surrounds the semiconductor layer of each vertical transistor in a lateral plane.

16. The semiconductor device of claim 15, wherein:
the leakage value of the semiconductor layer is lower than an intrinsic leakage value of monocrystalline silicon.

17. The semiconductor device of claim 15, wherein:
the semiconductor layer is a metal oxide semiconductor layer.

18. A method of forming a semiconductor device, comprising:
forming a plurality of capacitors;
forming a dielectric layer on the plurality of capacitors;
forming a conductive layer on the dielectric layer;
forming a plurality of through holes each penetrating the conductive layer and the dielectric layer to expose a corresponding one of the plurality of capacitors;
forming a semiconductor layer to cover a bottom and a sidewall of each through hole;
forming a gate dielectric layer to cover the semiconductor layer; and
forming a gate electrode on the gate dielectric layer in each through hole.

19. The method of claim 18, further comprising:
before forming the plurality of through holes, cutting the conductive layer to form a plurality of bit lines each extending along a second lateral direction.

20. The method of claim 18, further comprising:
forming a plurality of word lines each extending along a first lateral direction and coupled with the gate electrodes.
